(19) United States
(12) Patent Application Publication
(10) Pub. No.: US 2007/0171609 A1
(43) Pub. Date: Jul. 26, 2007

(54) Electronic equipment enclosure with passive thermal vent door control

(75) Inventors: Kenyon Kehl, Oro Valley, AZ (US); Tom J. Phielix, Tucson, AZ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/339,432

(22) Filed: Jan. 24, 2006

(51) Int. Cl. H05K 7/20

(52) U.S. Cl. 361/690

(57) ABSTRACT

A passive thermal actuator is used to control the position of a vent door mounted on an enclosure, to thereby selectively permit cooling air flow to one or more electronic units disposed within the enclosure. The passive thermal actuator is coupled to the vent door, is at least thermally coupled the electronics unit, and is comprised at least partially of a material, such as a shape memory alloy (SMA), that has a shape or volume that varies with electronics unit temperature variations. The passive thermal actuator, in response to the electronics unit temperature variations, selectively moves the vent door between its open and closed positions.

### FIELD OF THE INVENTION

The present invention relates to passive control of a vent door of an electronic equipment enclosure and, more particularly, to a passive thermal actuator that controls movement of a vent door to thereby control cooling air flow to an electronics unit in an electronic equipment enclosure.

### BACKGROUND OF THE INVENTION

Many electronic systems, such as those implemented in an aerospace environment, are convectively cooled using ambient, outside airflow. As such, these electronic systems may be subjected to potentially harsh environmental conditions, such as relatively low temperatures. Thus, when these systems are shutdown, the temperatures of the electronic units that comprise the systems may also be subject to relatively low temperatures, which may fall below normal operating temperature ranges. As a result, when these systems are subsequently energized (e.g., “cold started”), the electronic units may need to be heated up rapidly to within the normal operating temperature ranges.

As may be apparent from the above, convectively cooled electronic systems may need to implement disparate thermal energy dissipation strategies. In particular, when the systems are energized and operating, a relatively high heat dissipation strategy may need to be implemented by, for example, increasing convective heat transfer from system electronic units to the ambient environment. Conversely, when the system undergoes a cold start, a relatively low heat dissipation strategy may be needed by, for example, reducing the convective heat transfer to the ambient environment.

Hence, there is a need for a system and method of controlling convective heat transfer away from electronics units in electronic systems that can simply, easily, and inexpensively implemented and that can control electronic unit temperatures within normal operating ranges during normal system operations, while reducing heat dissipation from the system during a cold startup, to thereby enable a relatively rapid electronic unit temperature rise. The present invention addresses this need.

### SUMMARY OF THE INVENTION

The present invention provides a passive thermal actuator that simply, easily, and inexpensively controls the position of a vent door on an enclosure to thereby control convective heat transfer from the electronic units within the enclosure.

In one embodiment, and by way of example only, an electronic equipment assembly includes an enclosure, an electronics unit, a vent door, and a passive thermal actuator. The enclosure has an outer surface, an inner volume, and an air flow opening extending between the outer surface and the inner volume that is adapted to receive a flow of cooling air. The electronics unit is disposed within the enclosure inner volume and is configured, upon being energized, to generate heat. The vent door is rotationally mounted on the enclosure and is movable between an open position, in which a portion of the flow of cooling air flows through the air flow opening and into the inner volume to remove the heat generated by the electronics unit, and a closed position, in which the flow of cooling air is at least substantially inhibited from flowing through the air flow opening. The passive thermal actuator is disposed within the enclosure inner volume, is coupled to the vent door, at least thermally coupled the electronics unit, and is comprised at least partially of a material having a shape or volume that varies with electronics unit temperature variations. The thermal actuator is configured, in response to the electronics unit temperature variations, to selectively move the vent door between the open position and the closed position.

Other independent features and advantages of the preferred enclosure passive thermal vent door control will become apparent from the following detailed description, taken in conjunction with the accompanying drawings which illustrate, by way of example, the principles of the invention.

### BRIEF DESCRIPTION OF THE DRAWINGS

FIG. 1 is a simplified cross section view of an exemplary electronic equipment assembly that may incorporate a passive thermal vent door according to an embodiment of the present invention, and depicting the vent door in its closed position;

FIG. 2 depicts the exemplary electronic equipment assembly of FIG. 1 with the vent door in its open position;

FIG. 3 depicts a transformation versus temperature curve for an exemplary shape memory alloy (SMA) that decreases and increases in length as its temperature increases and decreases, respectively;

FIG. 4 is a simplified cross section view of an exemplary electronic equipment assembly that may incorporate a passive thermal vent door according to an alternative embodiment of the present invention, and depicting the vent door in its closed position; and

FIG. 5 depicts the exemplary electronic equipment assembly of FIG. 4 with the vent door in its open position.

### DETAILED DESCRIPTION OF A PREFERRED EMBODIMENT

Before proceeding with the detailed description, it should be appreciated that the following detailed description is merely exemplary in nature and is not intended to limit the invention or the application and uses of the invention. Furthermore, there is no intention to be bound by any theory presented in the preceding background or the following detailed description.

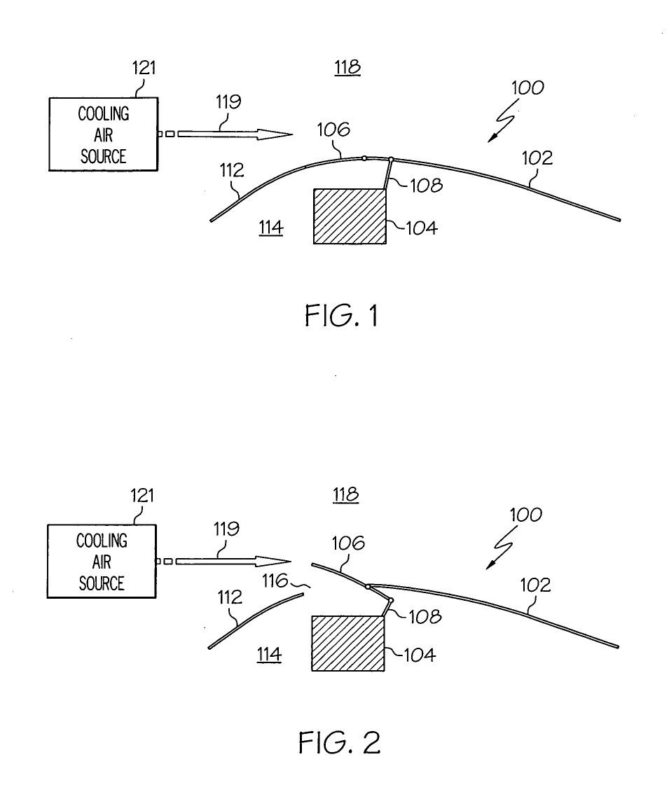

Turning now to FIGS. 1 and 2, a simplified cross section view of an exemplary electronic equipment assembly 100 is depicted. The assembly 100 includes an enclosure 102, an electronic unit 104, a vent door 106, and a passive thermal actuator 108. The enclosure includes an outer surface 112, an inner volume 114, and a vent opening 116 (see FIG. 2). The outer surface 112 is surrounded, at least partially, by an ambient environment 118 that supplies a flow of cooling air 119. As will be described in more detail further below, the cooling air is selectively supplied to the enclosure inner volume 114, via the vent opening 116 and vent door 106, to convectively remove heat that is generated by the electronic units 104 It will be appreciated that the flow of cooling air 119 could be supplied solely from the ambient environment 118 or from a cooling air source 121 such as, for example, a cooling fan.

The electronic unit 104 is mounted in the enclosure inner volume 114 and, like most other electronic devices, generates heat when energized. Although only one electronic unit 104 is depicted, it will be appreciated that this is done merely for clarity and simplicity of representation, and that more than one electronic control units 104 could be mounted in the enclosure inner volume 114. Moreover, it will be appreciated that the electronic units 104 may be implemented as any one of numerous electronic unit configurations. For example, the electronic unit 104 could be configured as one or more electronic circuit boards, individual electronic components, electronic circuit packages, one or more groups of individual electronic components, or one or more groups of individual electronic circuit boards. Furthermore, it will be appreciated that the electronic unit 104 may be mounted in the enclosure 102 using any one of numerous mounting configurations.

The vent door 106 is rotationally mounted on the enclosure 102 and is movable between a closed position and an open position. In the closed position, which is the position shown in FIG. 1, the vent door 106 at least substantially seals the vent opening 116. Thus, the cooling air 119 is at least inhibited from flowing into the enclosure inner volume 114. Conversely, in the open position, which is depicted in FIG. 2, the vent door 106 unseals the vent opening 116, placing the enclosure inner volume 114 in fluid communication with the ambient environment 118. As a result, at least a portion of the cooling air 119 flows into and through the enclosure inner volume 114, convectively cooling the electronic units 104 mounted therein. The vent door 106 is moved between the closed position and the open position in response to a force supplied from the passive thermal actuator 108.

The passive thermal actuator 108 is coupled to the vent door 106 and is at least thermally coupled to the electronic units 104. The passive thermal actuator 108, as its nomenclature denotes, is electrically passive, in that it does not move the vent door 106 in response to any electrical signal. Rather, the passive thermal actuator 108 responds solely to temperature variations within the enclosure 102, and more specifically to temperature variations of the electronics unit 104 (or units) to which it is thermally coupled. To implement this functionality, the passive thermal actuator 108 is comprised, at least partially, of a material having a shape or volume that varies with temperature. In particular, the passive thermal actuator 108 is preferably comprised, at least partially, of a two-way shape memory metal or metal alloy such as, for example, nickel-titanium, copper-zinc-aluminum, or copper-aluminum-nickel.

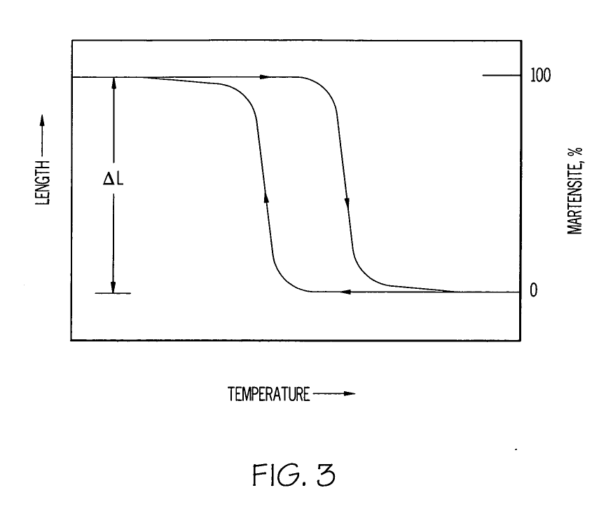

Shape memory metals and metal alloys, such as those delineated above, undergo a shape or volume change with variations in temperature. In particular, and as shown more clearly in FIG. 3, a typical two-way shape memory alloy, when heated, undergoes a partial phase transformation from a martensitic phase to an austenitic phase, with a concomitant decrease in length. Upon cooling, the shape memory alloy undergoes the reverse phase transformation, with a concomitant increase in length. It will be appreciated that other shape memory metals or metal alloys will undergo an increase in length when heated and, when cooled, will undergo a decrease in length. In either case, it is this change in length of the shape memory alloy that moves the vent door 106 between the closed and open positions.

The vent door 106 and passive thermal actuator 108 are configured such that when the passive thermal actuator i08, and thus the electronics unit 104 (or units) to which it is thermally coupled, is at or below a predetermined temperature the vent door 106 is in the closed position. As the passive thermal actuator 108 heats up, due to heat generation by the electronics unit 104 (or units), the passive thermal actuator 108 undergoes a shape change such that at or above the predetermined temperature the passive thermal actuator 108 moves the vent door 106 to the open position. In the open position, at least a portion of the cooling air 119 in the ambient environment 118 flows into and through the enclosure inner volume 114, convectively cooling the electronic units 104.

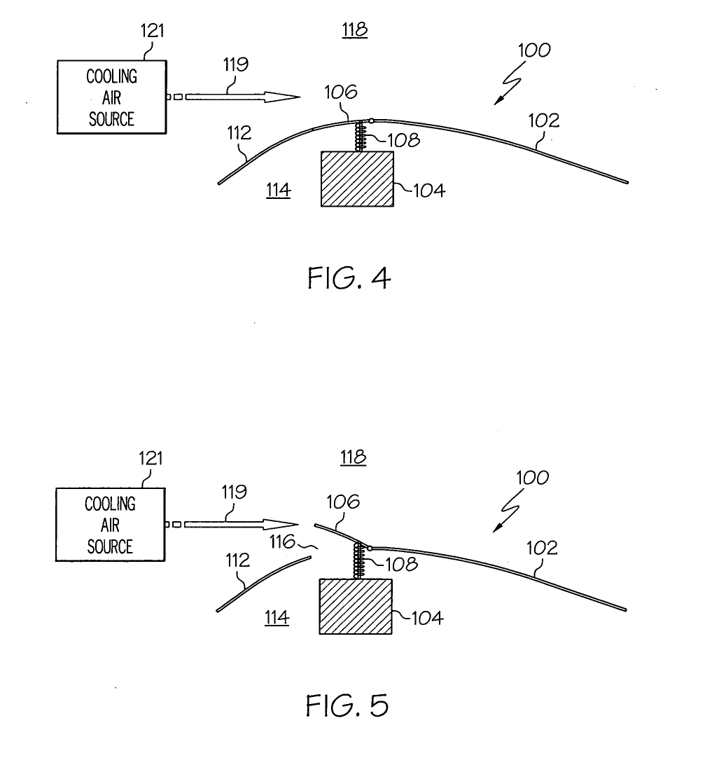

It will be appreciate that the configuration of the vent door 106 and passive thermal actuator 108 depicted in FIGS. 1 and 2 and described above is merely exemplary, and that other configurations may also be implemented. For example, in the embodiment depicted in FIGS. 1 and 2 the passive thermal actuator 108 is configured to contract when it is at or above a predetermined temperature, and to expand when it is below the predetermined temperature. In an alternative embodiment, which is shown in FIGS. 4 and 5, the passive thermal actuator 108 is configured to expand when it is at or above a predetermined temperature, and to contract when it is below the predetermined temperature.

In addition to alternative configurations for the passive thermal actuator 108, it will be appreciated that the vent door 106 could also be configured differently than what is depicted in FIGS. 1, 2, 4, and 5. In particular, the vent door 106 in these embodiments is biased toward the closed position (e.g., a normally-closed door), and the passive thermal actuator 108 is configured to overcome the bias and move the vent door 106 to the open position when the passive thermal actuator 108 is at or above the predetermined temperature. In alternative embodiments, however, the vent door 106 can be biased toward the open position (e.g., a normally-open door). In these alternative embodiments, the passive thermal actuator 108 is configured to overcome the bias and move the vent door 106 to the closed position when the passive thermal actuator 108 is at or above the predetermined temperature. It will be appreciated that the vent door 106 may be biased toward the open or closed position simply by gravity, or a bias force may be supplied from a device, such as a spring, for example.

The passive thermal actuator described herein provides for the relatively simple, easy, and inexpensive implementation of a system and method of controlling convective heat transfer away from electronics units in electronic systems. It additionally provides for a system and method of controlling electronic unit temperatures within normal operating ranges during normal system operations, while reducing heat dissipation from the system during a cold startup, to thereby enable a relatively rapid electronic unit temperature rise.

While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

We claim:

1. An electronic equipment assembly, comprising:
an enclosure having an outer surface, an inner volume, and an air flow opening extending between the outer surface and the inner volume, the air flow opening adapted to receive a flow of cooling air;
an electronics unit disposed within the enclosure inner volume and configured, upon being energized, to generate heat;
a vent door rotationally mounted on the enclosure and movable between an open position, in which a portion of the flow of cooling air flows through the air flow opening and into the inner volume to remove the heat generated by the electronics unit, and a closed position, in which the flow of cooling air is at least substantially inhibited from flowing through the air flow opening; and
a passive thermal actuator disposed within the enclosure inner volume, the passive thermal actuator coupled to the vent door and at least thermally coupled the electronics unit, the passive thermal actuator comprised at least partially of a material having a shape or volume that varies with electronics unit temperature variations, the thermal actuator configured, in response to the electronics unit temperature variations, to selectively move the vent door between the open position and the closed position.

2. The assembly of claim 1, wherein:
the vent door is biased toward the closed position; and
the passive thermal actuator is configured to overcome the bias and thereby move the vent door to the open position at a predetermined electronics unit temperature.

3. The assembly of claim 2, wherein the passive thermal actuator is configured to allow the vent door to return to the closed position at a second predetermined electronics unit temperature.

4. The assembly of claim 1, wherein:
the vent door is biased toward the open position; and
the passive thermal actuator is configured to overcome the bias to thereby move the vent door to the closed position at a predetermined electronics unit temperature.

5. The assembly of claim 4, wherein the passive thermal actuator is configured to allow the vent door to return the open position at a second predetermined electronics unit temperature.

6. The assembly of claim 1, wherein the material is comprised of a two-way shape memory metal or a two-way shape memory metal alloy.

7. The assembly of claim 1, wherein the material is a two-way shape memory alloy.

8. The assembly of claim 7, wherein the two-way shape memory alloy is selected from the group consisting of nickel-titanium, copper-zinc-aluminum, and iron-manganese-silicon.

9. The assembly of claim 1, further comprising:
a cooling air source operable to supply the flow of cooling air.

10. The assembly of claim 9, wherein the cooling air source comprises a fan.

11. An electronic equipment assembly, comprising:
an enclosure having an outer surface, an inner volume, and an air flow opening extending between the outer surface and the inner volume, the air flow opening adapted to receive a flow of cooling air;
an electronics unit disposed within the enclosure inner volume and configured, upon being energized, to generate heat;
a vent door rotationally mounted on the enclosure and movable between an open position, in which a portion of the flow of cooling air flows through the air flow opening and into the inner volume to remove the heat generated by the electronics unit, and a closed position, in which the flow of cooling air is at least substantially inhibited from flowing through the air flow opening; and
a shape memory alloy actuator disposed within the enclosure inner volume, the shape memory alloy actuator coupled to the vent door and at least thermally coupled the electronics unit, the shape memory alloy actuator comprised at least partially of a two-way shape memory alloy and configured, in response to the electronics unit temperature variations, to selectively move the vent door between the open position and the closed position.

12. The assembly of claim 11, wherein:
the vent door is biased toward the closed position; and
the passive thermal actuator is configured to overcome the bias and thereby move the vent door to the open position at a predetermined electronics unit temperature.

13. The assembly of claim 12, wherein the passive thermal actuator is configured to allow the vent door to return to the closed position at a second predetermined electronics unit temperature.

14. The assembly of claim 11, wherein:
the vent door is biased toward the open position; and
the passive thermal actuator is configured to overcome the bias to thereby move the vent door to the closed position at a predetermined electronics unit temperature.

15. The assembly of claim 14, wherein the passive thermal actuator is configured to allow the vent door to return the open position at a second predetermined electronics unit temperature.

16. A system comprising:
an airflow source operable to supply a flow of cooling air;
an enclosure having an outer surface, an inner volume, and an air flow opening extending between the outer surface and the inner volume;
an electronics unit disposed within the enclosure inner volume and configured, upon being energized, to generate heat;
a vent door rotationally mounted on the enclosure and movable between an open position, in which at least a portion of the cooling air flows through the air flow opening and into the inner volume to remove the heat generated by the electronics unit, and a closed position, in which the cooling air is at least substantially inhibited from flowing through the air flow opening; and
a passive thermal actuator disposed within the enclosure inner volume, the passive thermal actuator coupled to the vent door and at least thermally coupled the electronics unit, the passive thermal actuator comprised at least partially of a material having a shape or volume that varies with electronics unit temperature variations, the thermal actuator configured, in response to the electronics unit temperature variations, to selectively move the vent door between the open position and the closed position.

17. The assembly of claim 16, wherein:
the vent door is biased toward the closed position; and
the passive thermal actuator is configured to overcome the bias and thereby move the vent door to the open position at a predetermined electronics unit temperature.

18. The assembly of claim 17, wherein the passive thermal actuator is configured to allow the vent door to return to the closed position at a second predetermined electronics unit temperature.

19. The assembly of claim 16, wherein:
the vent door is biased toward the open position; and
the passive thermal actuator is configured to overcome the bias to thereby move the vent door to the closed position at a predetermined electronics unit temperature.

20. The assembly of claim 19, wherein the passive thermal actuator is configured to allow the vent door to return the open position at a second predetermined electronics unit temperature.
